(19) United States
(12) Patent Application Publication
(10) Pub. No.: US 2002/0046945 A1
(43) Pub. Date: Apr. 25, 2002

(54) High performance magnetron for DC sputtering systems

(75) Inventors: Akihiro Hosokawa, Cupertino, CA (US); Ravi Mullapudi, San Jose, CA (US)

Correspondence Address: GUY VINCENT MANNING, P.E., 405 PARK PLAZA, 2501 PARKVIEW DRIVE, FORT WORTH, TX, 76102, US

(73) Assignee: Applied Materials, Inc.

(21) Appl. No.: 09/875,816

(22) Filed: Jun. 6, 2001

Related U.S. Application Data
(63) Continuation-in-part of application No. 09/429,762, filed on Oct. 28, 1999.

(51) Int. Cl. C23C 14/34

(52) U.S. Cl. 204/298.18; 204/298.17; 204/298.19; 204/298.23; 204/298.11

(57) ABSTRACT

A sputter deposition apparatus and method includes perimeter magnets oriented an angle relative to the plane of the sputter target, either by magnetizing or by physically orienting the magnets at the chosen angle. The resulting magnetic flux extends radially outward, away from the central axis of the target, toward and beyond the target perimeter. This causes the return path of the flux to pass over the target surface more parallel to the plane of its sputtering surface. This spreads sputter erosion over a greater area of the target surface and mitigates development of sputtering grooves. Since target erosion is more uniform, more target material is used for sputter deposition, deterring waste. Each target can be used longer before the target material is penetrated, resulting in fewer target replacement cycles for a given volume of workpiece coating, raising the deposition chamber capacity factor.

This is a continuation-in-part of Application No. 09/429,762, filed Oct. 10, 1999, now pending.

### BACKGROUND OF THE INVENTION

1. Field of the Invention

The invention relates generally to equipment for performing sputter deposition on an electronic workpiece such as a flat panel display, and particularly to a tilted sputtering target and shield for preventing particles of contaminants from falling from the target onto the workpiece. Still more particularly, this invention relates to an arrangement and orientation of accelerator magnets that improves the efficiency of target material and deposition chamber utilization.

2. Description of Related Art

Large flat panel displays and other electronic devices generally are manufactured by a series of process steps in which successive layers of material are deposited on a workpiece, such as a glass substrate, and then patterned. Some of the deposition steps typically are performed by sputter deposition, which is deposition by sputtering material from a target.

In sputter deposition, the sputtering target and the workpiece are positioned within a vacuum chamber in which a gas having relatively heavy atoms, such as argon, is excited to a plasma state. A negative DC or alternating voltage on the target accelerates the argon ions from the plasma to bombard the target. Some of the bombardment energy is transferred to material on the surface of the target, so that molecules of target material are ejected or “sputtered” from the target. The workpiece is positioned so that a large portion of the sputtered target material deposits on the workpiece.

Some types of commonly used target material tend to produce particles of contaminants that can ruin the electronic device being manufactured if the particles fall on the workpiece. For example, indium tin oxide (ITO) targets typically contain at least one percent impurities. As the target is sputtered, the impurities can agglomerate into particles as large as 1 mm before they fall off the target. Another type of target that tends to produce particles of contaminants is a target constructed as a matrix of tiles instead of as a single, monolithic target. Arcing in the gaps between tiles can dislodge particles of the material used to bond the tiles to a backing plate.

The problem of contaminant particles falling on the workpiece is most severe when the target and workpiece are both oriented horizontally, with the target directly above the workpiece. In that case, almost all particles that fall off the target will lodge on the workpiece.

To overcome this problem, some conventional sputter deposition chambers orient the target and the workpiece vertically, with the workpiece alongside rather than below the target. In such designs, most particles that fall off the target will fall harmlessly below the target rather than onto the workpiece. However, it is difficult to mechanically support a large glass substrate in a vertical orientation without excessively stressing and even cracking the substrate. Therefore, a need exists for an apparatus and method for sputter depositing material on a workpiece that minimizes the deposition of contaminant particles on the substrate and that can be performed with a horizontally oriented substrate.

A further difficulty arises in the utilization factor for both deposition chamber operating time and for target life. As target bombardment proceeds, gas ion current distribution across the target correlates with magnetic flux density, which typically is non-uniform across the target surface. Erosion thus occurs fastest where magnetic flux is greatest, creating one or more sputtering grooves in the target surface where target material has been dislodged by bombardment. Target tiles typically begin with a uniform thickness of four to ten millimeters, and must be replaced when the sputtering groove depth reaches this thickness. A method and apparatus that disperses the accelerator magnetic field across the target surface would mitigate development of sputtering grooves and extend target life by utilizing more of the tile for deposition on the substrate.

Changing tiles in deposition chambers is costly. Breaking the vacuum to replace tiles involves cooling down the chamber from operating temperatures, replacing the target, re-heating the chamber to bake out water vapor absorbed from ambient air, and burning-in time to remove an oxide layer which inevitably forms on the tiles, all with concomitant energy consumption in the process. The longer a target tile can be used before having to be changed, therefore, the fewer changing cycles required for a given amount of substrate deposition.

Various devices have been adapted to overcome uneven target erosion. Morrison, U.S. Letters Patent No. 4,265,729, for example, describes configuring multiple magnets to influence magnetic flux patterns in an effort to mitigate waste in portions of target real estate, particularly by enhancing flux parallel to the target surface. Morrison largely employs solid magnet configurations, however, which aggravate capital cost and complexity and deviate significantly from conventional practices. An apparatus and method which conforms to conventional, large substrate magnetron configurations while enhancing magnetic flux parallel to the target surface would improve target utilization while minimizing complexity and cost of improvements to sputtering chambers.

### SUMMARY OF THE INVENTION

The invention is a sputter deposition apparatus and method comprising a tilted sputtering target and a shield that intercepts particles that may fall from the target so that the particles do not deposit on the workpiece. The invention permits the workpiece to be oriented horizontally.

More specifically, the sputtering target is mounted higher than the workpiece position and is oriented at an angle of 30 to 60 degrees relative to the vertical axis. The shield occupies an area such that any vertical line extending vertically downward from the front surface of the target to a point on the workpiece intersects the shield above said point.

Another aspect of the invention is a pair of sputtering targets oriented at an angle of 30 to 60 degrees relative to, and symmetrically relative to, a vertical plane. This symmetrical, tilted arrangement overcomes deposition nonuniformity that could occur with a single, tilted target. Each target includes two sets of magnetic poles, the first set being mounted adjacent the rear surface of the target, and the second set being mounted adjacent the perimeter of the target so as to encircle the first set. This magnet arrangement enables the magnets to be spaced close to the target to maximize the strength of the magnetic field adjacent the target, and thereby maximize the sputter deposition rate.

A further enhancement of the arrangement involves orienting the magnetic field from the perimeter magnets at an angle between thirty (30°) degrees and sixty (60°) degrees, with an optimum angle of approximately forty-five (45°) degrees, relative to the plane of the target. This can be achieved either by magnetizing or by physically orienting the perimeter magnets at the chosen angle. The resulting magnetic flux extends laterally beyond the target tile perimeter, causing the flux lines passing over the tile surface to be more parallel to the plane of the target tile and less concentrated at the poles. This spreads sputter erosion over a greater area of the target tile and attenuates development of sputtering grooves, thereby allowing a target to be used longer before the tile material is penetrated. Since tile erosion is more uniform, more of the expensive target material on a given tile is used for sputter deposition and less is wasted. Since each tile is used longer before having to be replaced, fewer tile changing cycles are necessary for a given volume of substrate coating, and the deposition chamber capacity factor rises.

### BRIEF DESCRIPTION OF THE DRAWINGS

The novel features believed characteristic of the present invention are set forth in the appended claims. The invention itself, however, as well as a preferred mode of use and further objects and advantages thereof, will best be understood by reference to the following detailed description of one or more illustrative embodiments when read in conjunction with the accompanying drawings, wherein:

FIG. 1 is a partially schematic, sectional side view of a sputter deposition chamber having two tilted targets with shields according to the invention.

FIG. 2 is a detailed view of one of the targets and shields of FIG. 1.

FIG. 3 is a top plan view of the magnet structure behind one target.

FIG. 4 is a top plan view of the magnetic pole piece behind one target.

FIG. 5 is a partially schematic, sectional side view of an alternative embodiment of the chamber of FIG. 1 having reinforced shields.

FIG. 6 is a top plan view of a sputter deposition chamber having four tilted targets and one horizontal target.

FIG. 7 is an elevation view of the chamber of FIG. 6.

FIG. 8 is a simplified version of FIG. 2 showing another alternate embodiment of the invention.

FIG. 9 is a detail of the magnet and target portion of FIG. 2, showing the magnetic field and ion path distributions resulting from the magnetic arrangement of the preferred embodiment of FIGS. 1-7.

FIG. 10 is a cross section through the target corresponding to the magnet orientation of FIG. 9.

FIG. 11 is a cross section through the target corresponding to the magnet orientation of FIG. 8.

FIG. 12 is a detail similar to FIG. 9 but with the perimeter magnets magnetized at an oblique angle relative to the target, as in FIG. 8.

FIG. 13 is a detail similar to FIG. 12 but with the perimeter magnets physically oriented at an oblique angle relative to the target.

### DETAILED DESCRIPTION OF A PREFERRED EMBODIMENT

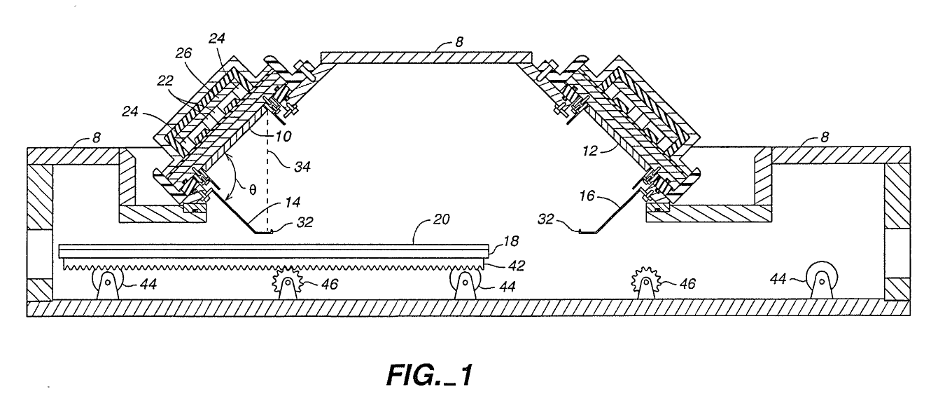

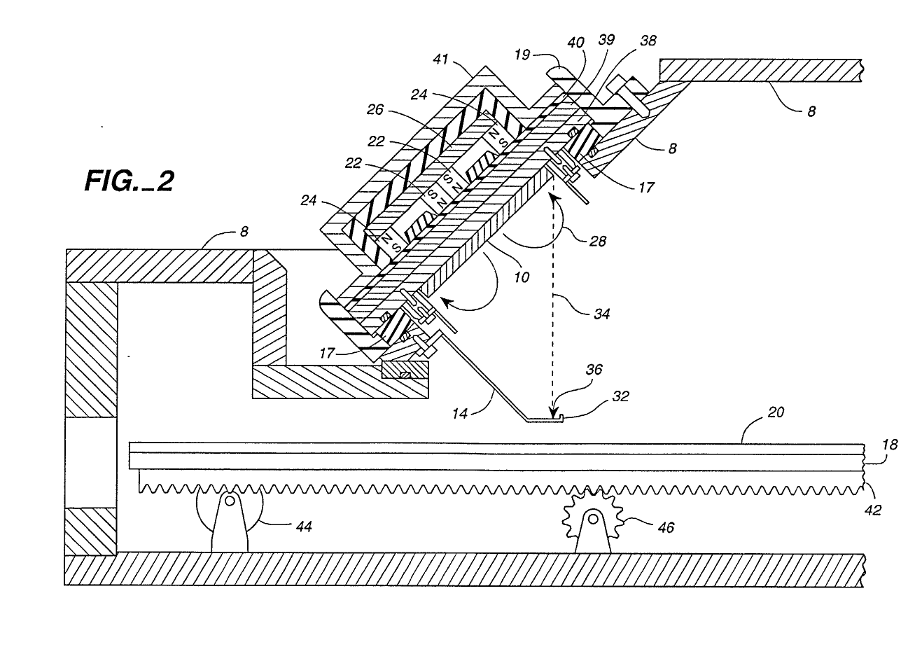

FIGS. 1 and 2 shows a sputter deposition chamber 8 having two tilted sputtering targets 10, 12, where each target has a respective contaminant blocking shield 14, 16 according to the invention. The illustrated chamber is designed to accommodate a large rectangular workpiece or substrate of the type used to fabricate electronic video displays. Such a substrate currently can be as large as 650 mm×800 mm (width×length), and even larger substrates are expected to enter widespread use in the near future.

It is expensive and difficult to construct a sputtering target and magnet as large as such a substrate. Consequently, the currently preferred embodiment of the invention employs long, narrow rectangular targets 10, 12, each of which has a length greater than that of a substrate, but a width much smaller than that of the substrate. A carrier 18 slowly moves the substrate 20 horizontally past the targets so that material sputtered from the targets covers the entire substrate. In the illustrated embodiment, each target is 10 cm wide and 1 meter long.

Any conventional transport mechanism can be installed in the chamber to slowly move the substrate past the targets. The illustrated embodiment employs a rack and pinion mechanism in which a toothed rack 42 is mounted on the bottom of the substrate carrier 18. Pinion gears 46 are mounted along the length of the chamber at spaced intervals no greater than the width of the carrier 18, so that the rack always engages at least one pinion gear. A motor, not shown, rotates the pinion gears. Freely rotating idler wheels 44 support the carrier 18 at points between the pinion gears.

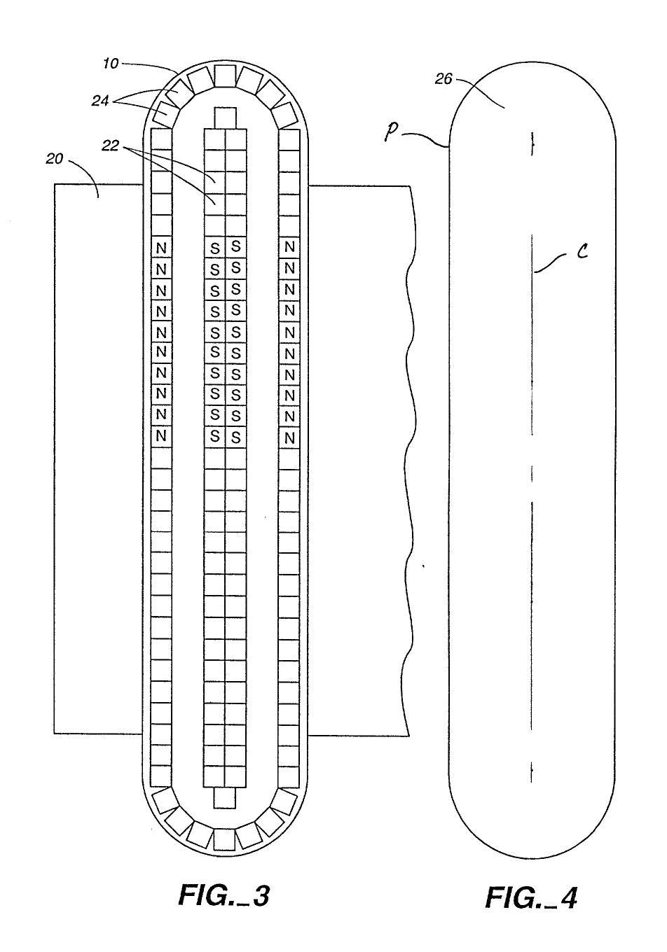

FIGS. 2 and 3 show the arrangement of magnets above (i.e., behind) the targets. An array of permanent magnets 24 produces a magnetic field having a south pole along the entire perimeter P of the target and having a north pole along the long, central axis C (FIG. 4) of the target. The north pole of the magnet array consists of two rows of rectangular magnets 22 along central axis C of the target, each magnet having its magnetic axis oriented perpendicular to the target, with the north pole adjacent the target. The south pole of the array consists of one row of magnets 24 radially separated from central axis C and arrayed along perimeter P. Outer magnets 24 are identical to inner magnets 22, except that the south pole of each outer magnet 24 is adjacent the target. A ferrous pole piece 26 (FIGS. 2 and 4) magnetically connects the south poles of the inner magnets to the north poles of the outer magnets so as to form a “magnetic circuit.” This magnetic circuit produces a magnetic field depicted by arrows 28 in FIG. 2.

Alternatively, the north and south poles can be interchanged without affecting the performance of the apparatus. (In FIG. 3, only a sampling of the magnets are labeled with the letters S or N, but all of the inner magnets 22 have the same magnetic orientation as the ones labeled S, and all of the outer magnets 24 have the same orientation as the ones labeled N.) An electrical power supply, not shown, supplies a large alternating voltage or negative DC voltage, typically on the order of −600 volts, to the target 10, 12. A dielectric spacer 17 electrically insulates the target from the electrically grounded chamber wall 8, and a dielectric outer cover 19 protects personnel from accidental contact with the high voltage on the target.

The principles of operation of a magnetron sputtering system are well known. In operation, a relatively heavy gas such as argon is supplied into the vacuum chamber. A vacuum pump, not shown, maintains a very low gas pressure within the chamber, typically 1 to 5 mTorr. The magnetic field 28 tends to trap free electrons in the vicinity of the target so that they circulate around a closed, oval path parallel to the gap between the inner magnets 22 and the outer magnets 24. As in a conventional magnetron sputtering target, the two ends of each target and pole piece are semi-circular in order to provide at least a minimum turning radius for the circulating electrons.

The circulating electrons collide with and ionize the argon gas atoms. The large negative DC or alternating voltage on the target 10, 12 accelerates the argon ions toward the target. The argon ions bombard the front surface of the target so as to eject or “sputter” material from the surface of the target. Because the workpiece 20 is in front of the target, a significant portion of the sputtered target material deposits on the workpiece.

Each molecule of material sputtered from the target travels in a straight trajectory away from the target, but the trajectories of different molecules of sputtered material are distributed over a range of angles. The distribution range depends on the specific material being sputtered, but for almost all materials the trajectories of the sputtered material are concentrated in the range of plus or minus 30 degrees from a line perpendicular to the front surface of the target.

As stated above in the Background of the Invention, certain types of target material, such as indium tin oxide (ITO), commonly include organic contaminants that aggregate during sputtering of the target and ultimately flake off as particles that can fall onto the workpiece 20. In addition, a target constructed as a matrix of tiles instead of as a single, monolithic target can experience arcing in the gaps between tiles that can dislodge particles of the material used to bond the tiles to a backing plate.

To prevent such particles from contaminating the workpiece, the invention includes a shield 14, 16 below each target, and each target 10, 12 is tilted relative to the vertical axis. The shield intercepts particles falling from the target before they reach the workpiece, because the shield occupies an area such that any vertical line extending downward from the target to the workpiece position intersects the shield at a point above the workpiece position. Preferably the lower edge of the shield includes an upward-extending lip 32 that prevents particles from sliding off the lower edge of the shield.

In a conventional sputter deposition chamber having a horizontally oriented target, the workpiece must be positioned directly below the target in order to receive the material sputtered from the target. This precludes positioning a shield between the target and the workpiece to intercept contaminant particles falling off the target, because such a shield would block almost all the sputtered material. Conversely, a vertically oriented target would not permit the use of a horizontally oriented workpiece, because the material sputtered from a vertically oriented target will have horizontal trajectories, and hence would mostly fly over a horizontal workpiece.

In the present invention, the tilt of the target provides both a vertical and a horizontal component to the trajectories of the sputtered target material. The vertical component allows the substrate to be oriented horizontally without the sputtered material flying over the substrate, and the horizontal component allows the substrate to be laterally offset from the target so that a shield below the target can intercept particles of contaminants. The tilt of the target relative to the vertical axis should be in the range of 30 to 60 degrees, preferably about 45 degrees.

The two principal design parameters for the shield 14, 16 are: (1) the length by which the shield extends away from the target, and (2) the angle θ between the shield and the plane of the front surface of the target. The length of the shield should be great enough so that a vertical line 34 extending downward from the upper edge of the target toward the workpiece position intersects the shield at a point 36 above the workpiece position (see FIG. 2).

The shield in the illustrated preferred embodiment is perpendicular to the front surface of the target. Alternatively, the shield can be angled more upward or more downward so that the angle θ between the shield and the target is less than or greater than ninety degrees, respectively. Decreasing the angle between the shield and the target has the advantage of allowing the target to be mounted lower and hence closer to the workpiece. However, it increases the amount of material sputtered from the target that is blocked by the shield from reaching the workpiece. Increasing the angle has the opposite effect: it has the advantage of decreasing the amount of sputtered target material that is blocked by the shield, but it has the disadvantage of requiring the target to be mounted higher above the workpiece.

Preferably, the height of the target above the workpiece should not be so great that there is a high probability that material sputtered from the target will collide with gas atoms before reaching the workpiece. At the range of chamber pressures typically used for sputter deposition, 1 to 5 mTorr, a preferred height would be one at which the average path length of sputtered material from the target to the workpiece is 15 to 20 cm. Equivalently, the target preferably is positioned at a height above the workpiece such that a line that is perpendicular to the target and extends from the center of the target to the workpiece is 15 to 20 cm long. For a target tilted at a 45 degree angle as in the illustrated embodiment, this means the center of the target would be about 10 to 14 cm above the workpiece. Reducing the chamber pressure would increase the mean free path of sputtered target material, hence would permit a greater target height.

To minimize the distance between the target and the workpiece, the workpiece preferably should be mounted as close as possible to the shield 14, 16 while deposition is being performed. In the preferred embodiment, the carrier 18 moves the workpiece 20 along a planar, horizontal path that is only 5 mm below the lower edge of the shield.

Because the target is tilted and is laterally offset relative to the substrate, the sputtered target material generally arrives at the substrate from one side. For example, in FIG. 1 the sputtered material from the leftmost target 10 generally arrives at the substrate 20 from the left side. If the top surface of the substrate is flat, this directivity should not adversely affect the deposition of target material on the substrate. However, if the top surface of the substrate is patterned with openings that are to be filled with target material, as when fabricating metal contacts or vias, then the directivity will be undesirable because in each opening more target material will be deposited on the side wall of the opening furthest from the target. In the example of FIG. 1, each opening will have a maximum amount of material from target 10 deposited on the right side wall of the opening, and a minimum amount deposited on the left side wall.

To eliminate this directivity, the illustrated preferred embodiment employs two targets tilted in opposite directions. Specifically, the leftmost target 10 directs sputtered material toward the right, and the rightmost target 12 directs sputtered material toward the left. The two targets in combination produce uniform deposition of sputtered target material on all sides of an opening in the substrate.

As stated above, a single target 10 may suffice if the top surface of the substrate does not include deep, narrow openings to be filled with sputtered material. Therefore, the invention can be implemented with a single target 10 and a single shield 14, even though two targets are preferred.

Each shield 14, 16 preferably should be electrically isolated from the target 10, 12 in order to avoid erosion of the shield by ion bombardment. The shield can be electrically floating or, as shown in FIGS. 1, 2 and 5, it can be electrically grounded to the chamber wall 8.

To maximize the rate of sputter deposition, the distance between each of the magnets 22, 24 and the front surface of the target 10 (the surface exposed to sputtering) should be as small as possible relative to the width of the front surface of the target and relative to the gap between the magnetic poles of opposite polarity adjacent the target. In the illustrated embodiment, the latter gap is the gap between the inner magnets 22 and the outer magnets 24. Minimizing the magnet-to-target distance will maximize the strength of the magnetic field in the region of the argon ions immediately adjacent the target front surface, which will maximize the flux density of argon ions bombarding the target. Preferably the average distance between the magnets and the front surface of the target is less than 100% (more preferably, less than 50%) of the width of the front surface of the target, and is less than 200% (more preferably, less than 100%) of the average gap between the magnetic poles of opposite polarity adjacent the target. (If the target has an elongated shape as in the illustrated embodiment, its “width” and “length” are the short and long dimensions, respectively, of the front surface of the target.)

The preferred arrangement of two oppositely tilted targets, shown in FIG. 1, minimizes the distance between each of the magnets 22, 24 and the front surface of the adjacent target 10 or 12 by mounting the magnets directly behind each target. Referring to the left target 10 shown in FIG. 2, the target is bonded to a first backing plate 38 whose function is to provide mechanical strength to the target. A second backing plate 39 abutting the first backing plate includes channels through which water can be pumped to cool the target and the magnets. The backing plates should be constructed of material that is non-magnetic (i.e., non-ferrous) and that is mechanically strong, such as copper or aluminum. A dielectric sheet 40 electrically insulates the high voltage on the target and backing plates from the magnets and the outer cover 41.

In the illustrated prototype, the target is 8 mm thick, the first and second backing plates are each 10 mm thick, and dielectric sheet is 3 mm thick. The distance from each of the magnets 22, 24 to the front surface of the target 10 is the sum of these thicknesses, which equals 31 mm. Since each target is 100 mm wide, the gap between the inner and outer magnets is about 40 mm. Therefore, the 31 mm distance between each of the magnets and the front surface of the target is less than the 40 mm gap between the magnetic poles adjacent the target, and it is less than 50% of the 100 mm width of the target.

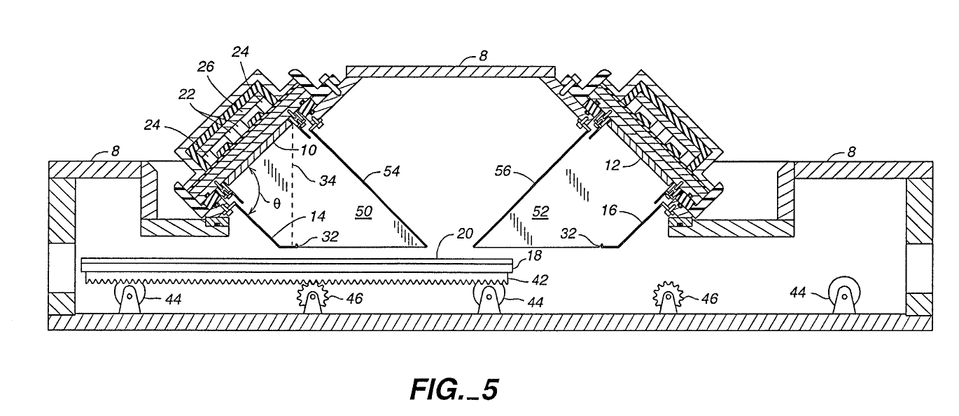

If the workpiece 20 is positioned as close to the lower edge of the shield as it is in the preferred embodiment (5 mm), the shield 14, 16 should be rigid enough that it cannot be inadvertently deflected so as to contact and thereby damage the workpiece. FIG. 5 shows an alternative embodiment in which the shield is reinforced to improve its rigidity. Specifically, each shield 14, 16 is welded to two sidewalls, which are welded to a top wall, which is bolted to the target assembly. FIG. 5 shows the left shield 14 welded to two side walls 50, and a top wall 54 welded to the two side walls. The shield 14, side walls 50, and top wall 54 in combination form a rectangular tube. Similarly, the right shield 16 is welded to two side walls 52, which are welded to a top wall 56. The side walls prevent the shield from flexing.

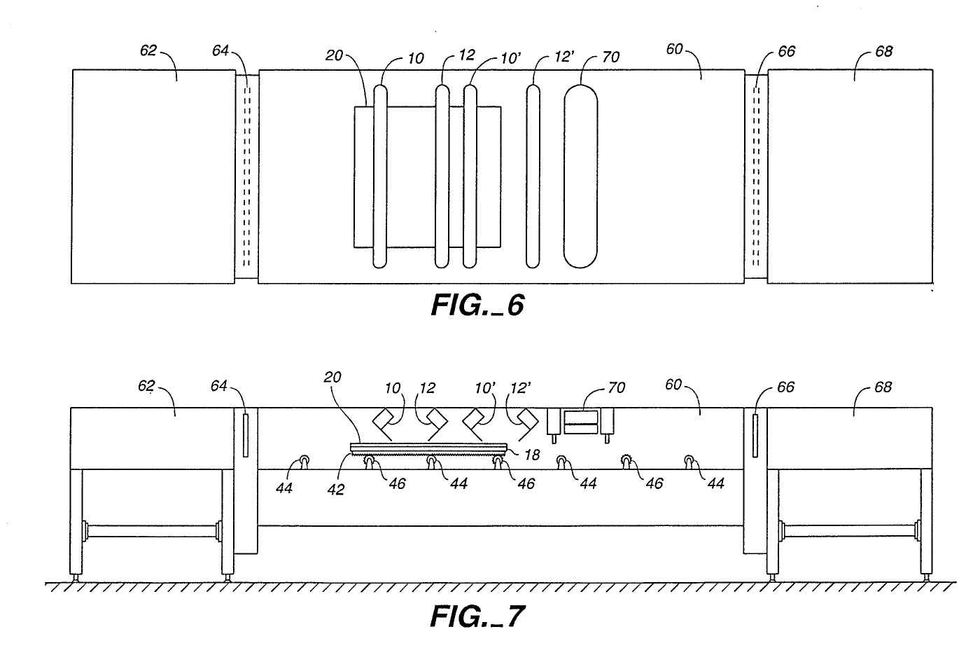

FIGS. 6 and 7 illustrate how several sputtering targets can be arranged within a single sputter deposition vacuum chamber 60 to deposit successive layers of target material on the workpiece 20. The carrier 18 slowly and continuously conveys the workpiece from left to right below successive sputtering targets.

Specifically, the workpiece 20 enters via entrance load lock chamber 62. Lift pins, not shown, raise the workpiece above the carrier 18 and then deposit the workpiece onto the carrier. The carrier transfers the workpiece from the input load lock chamber 62, through the vacuum valve 64, and into the sputter deposition vacuum chamber 60.

The carrier then moves the workpiece below the first pair of indium tin oxide (ITO) targets 10, 12 which deposit a first layer of ITO film on the substrate. The carrier continues moving the substrate so that it passes below the second pair of ITO targets 10′, 12′, which deposit a second layer of ITO film on the substrate. As the carrier continues moving the substrate to the right, it passes below a MoCr or Cr target 70, which deposits a MoCr or Cr layer over the previously deposited ITO layers. Finally, the carrier transfers the workpiece from the sputter deposition vacuum chamber 60, through vacuum valve 66, and into the exit load lock chamber 68.

The tilted targets and shields of the present invention are used to deposit the ITO layers because ITO targets typically produce particles of organic contaminants, as explained earlier. However, a conventional horizontal target 66 without a shield can be used for depositing the MoCr or Cr layer, because MoCr and Cr targets are readily available with a high degree of purity that does not generate particles of contaminants.

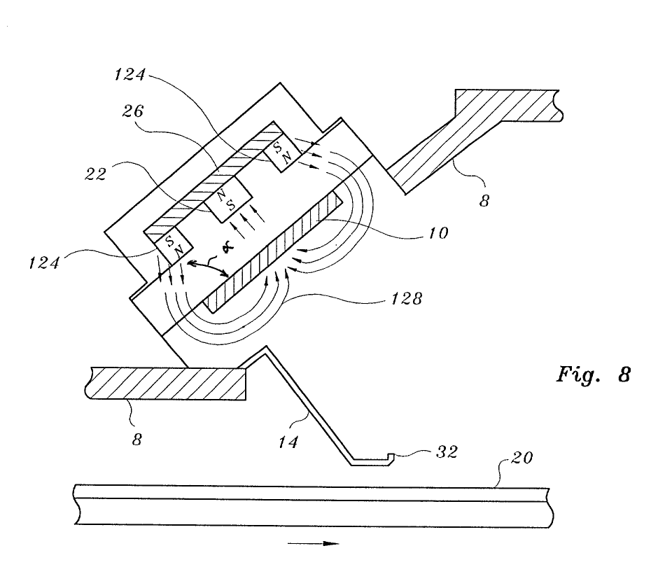

FIG. 8 illustrates a second alternate embodiment of the invention which may be used with either or both of the previously discussed embodiments. In the embodiment of FIG. 8, magnetic flux lines 128 of perimeter magnets 124 spread radially outward, away from central axis C, toward and beyond perimeter P of target 10. This has the desired effect of better distributing the oval path of the circulating free electrons over the surface of target 10, increasing the magnetic flux density parallel to the surface of target 10, and increasing ion current. The result is improved utilization of target 10 and deposition chamber 60, as discussed below.

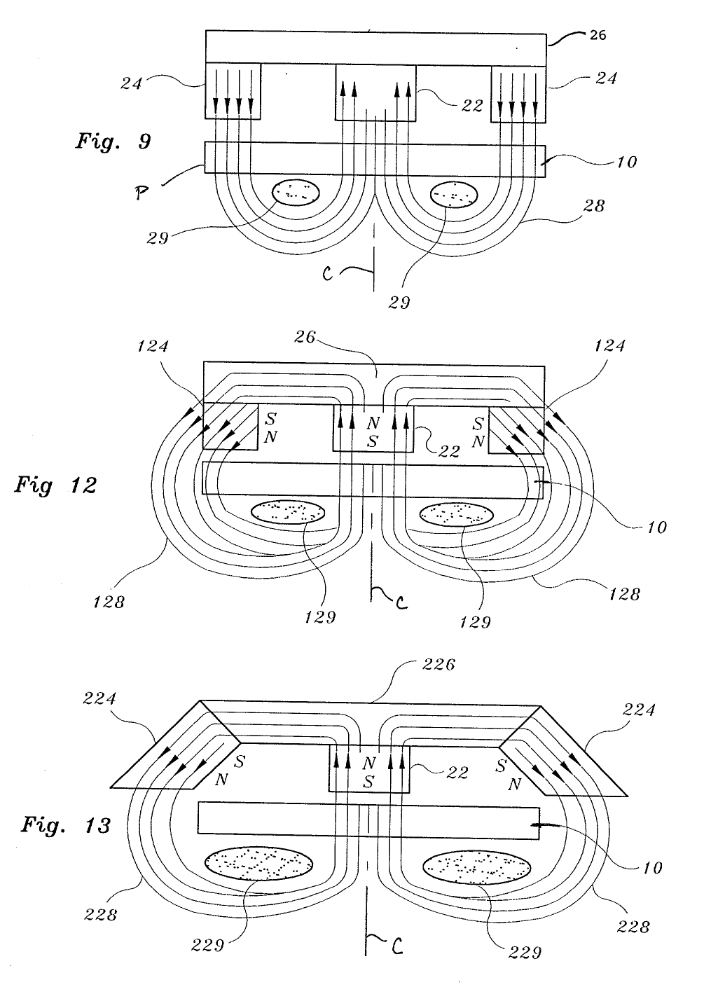

FIG. 9 details the magnetic flux 28 pattern occurring in the preferred embodiment (FIGS. 1-7), where perimeter magnets 24 are arrayed and magnetized normal to the surface of target 10. In the case of a static field, magnetic flux 28 emanates from perimeter magnets 24 substantially normal to the plane of target 10, and returns densest along a path also substantially normal to target 10 directly beneath interior magnets 22. Of course, in a dynamic field induced by electromagnets, the polarity oscillates, but the distribution remains substantially as depicted in FIG. 9. In either case, free electrons circulate within the resulting plasma region 29 formed adjacent the front surface of target 10 between interior magnets 22 and exterior magnets 24. Plasma region 29 occupies relatively little of the total surface area of target 10. The free electrons collide with gas ions venturing into this region, ionizing them. Once ionized, the gas ions are attracted to the front surface of target 10 where they collide with target material molecules. Though the gas ions are generally biased toward target 10 by the electric field from the voltage applied to target 10, they tend to intersect target 10 nearest the poles of inner magnets 22 and outer magnets 24, because magnetic flux 28 density is greatest in this region.

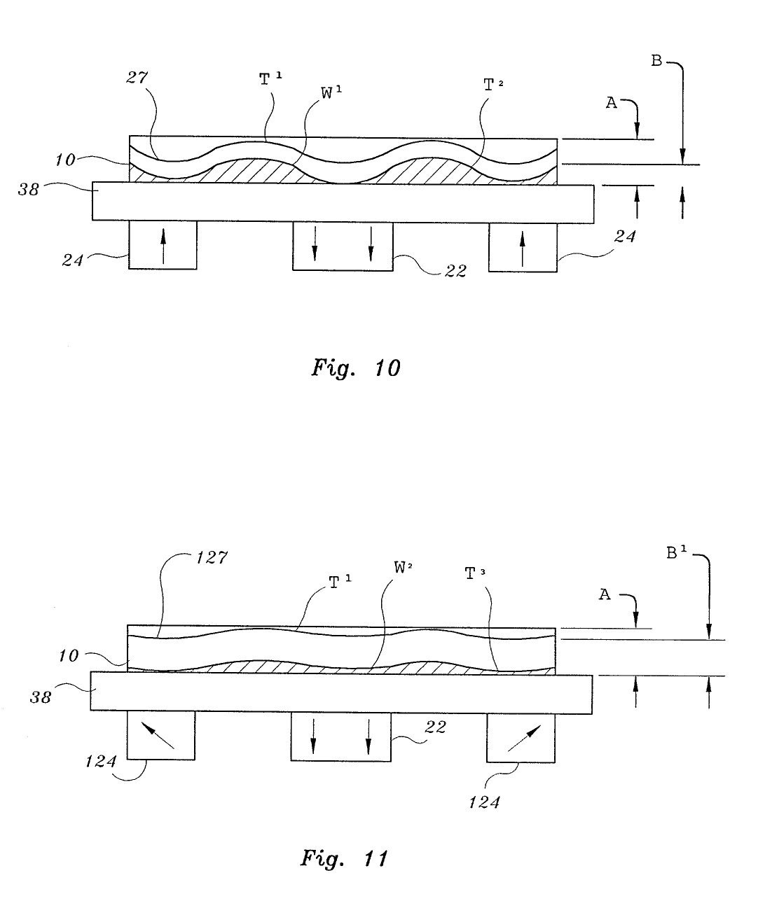

FIG. 10 illustrates a sub-optimal effect on target 10 of this arrangement. Perimeter magnets 24 are oriented normal, or perpendicular, to target 10, as in FIG. 9. Flux 28 paralleling the surface of target 10 is minimal, and ion current low, allowing some gas ions to drift until they are swept toward target 10 in the region of the higher magnetic flux 28 nearer the poles of magnets 22, 24. Since flux 28 is densest nearest the magnet poles, gas ion bombardment of target 10 also maximizes in the same locality. This wears target 10 unevenly, deepening grooves 25, 27 where the gas ions intersect the surface of target 10.

Continuing with FIG. 10, target 10 begins operation with an initial thickness, A, substantially uniform across its entire surface. After operation period T¹, grooves 25, 27 erode to a maximum depth, B. With further operation, depth B eventually approaches initial thickness A at time T². Target 10 then must be replaced lest target tile bonding material contaminate substrate 20. Target utilization time thus is limited to period T², and waste target material W¹ must be abandoned or recycled and a new target 10 installed, requiring a tile changing cycle of chamber 60.

FIG. 11 illustrates improvement achieved by the alternate embodiment shown in FIG. 8. Magnetizing perimeter magnets 124 at an acute magnetizing angle α (FIG. 8) relative to the plane of target 10 shifts their greatest flux density radially outward, away from central axis C, toward and beyond perimeter P of target 10. Magnetizing angle α preferably is between 30 and 60 degrees, optimally 45 degrees, relative to the plane of target 10. Angling the magnetization radially outward at perimeter P widens the path of free electrons in the resulting plasma 129 between inner and outer magnets 22, 124. This in turn increases the probability of ionizing contact with gas ions because of the larger plasma region 129. More importantly, however, it causes magnetic flux 128 to become more parallel to and uniform across target 10, and spreads out the resulting bombardment of gas ions over a larger portion of the surface of target 10. Erosion grooves 125, 127 still develop, but more slowly and over a wider area. Specifically, their maximum depth B¹ is substantially shallower for the same operation time T¹ than depth B of grooves 25, 27. Eventually, depth B¹ also reaches thickness A, but it takes longer to do so. Because grooves 125, 127 are so much shallower than grooves 25, 27, target 10 utilization time T³ (FIG. 11) is considerably greater than T² (FIG. 10).

This translates into several advantages over the ninety (90°) degree pole orientation of FIG. 9. First, because target 10 utilization time is greater, fewer changing cycles are required for deposition chamber 60, with concomitant savings in energy and improved capacity factor for chamber 60. Second, a greater volume of target 10 is eroded during utilization time T³, thus reducing target tile waste (W² compared to W¹), and conserving the valuable, high-purity target material itself. Third, more flux 128, 228 density within region 129, 229 means greater ion current for a given voltage, or, a lower voltage for a given power level. This conserves energy for a given substrate coating and reduces target material splash during bombardment, making sputter deposition more predictable.

FIGS. 12 and 13 illustrate two ways that this alternate embodiment may be constructed. In FIG. 12, perimeter magnets 124 are oriented physically the same as in FIG. 9. This allows employment of the same geometry described above for the preferred embodiment. All that changes is the distribution of magnetic flux 128 and free electron path 129. The physical gap between interior magnets 22 and perimeter magnets 124 is substantially the same, and the relative effects of sputter trajectory are substantially unaffected. Thus, in the prototype illustrated in FIG. 8, the distance from the magnets to the front of target 10 remains 31 mm, and the gap between inner magnets 22 and outer magnets 124 remains about 40 mm.

FIG. 13 illustrates a variation on FIG. 12 where perimeter magnets 224 are oriented physically to coincide with the desired magnetization angle α, as shown in FIG. 12. Electron 17 path 229 is somewhat further improved by being spread over more of target 10. This comes at a cost, however. First, it requires physical changes to other hardware in deposition chamber 60. Specifically, the interface between perimeter magnets 224 and pole piece 226 is shown beveled to mate with the similarly beveled, upper portion of perimeter magnets 224. Likewise, magnets 224 are beveled at their opposite poles to interface optimally with target 10 through dielectric insulator 40, as discussed above. One having ordinary skill in the art will recognize, of course, that other means of closing the magnetic path of flux 228 may be utilized without departing from the spirit and scope of the invention. Nevertheless, physical re-orientation of perimeter magnets 224 involves some increase in capital cost of deposition chamber 60.

Physically orienting perimeter magnets 224 as shown also increases the gap between them and interior magnets 22. Further, since they extend radially beyond perimeter P of target 10, separation of perimeter magnets 224 from target 10 also increases. For example, if magnets 22, 24 of the preferred embodiment each are 14 mm long, orienting magnets 224 at 45° increases the gap between inner and outer magnets by approximately 14 mm, or to a total of approximately 54 mm, requiring an increase in the overall perimeter dimension of outer cover 41. Likewise, the resulting separation from target 10 increases by approximately 3 mm, or to approximately 34 mm. Neither increase negatively affects performance, but the physical dimensions of deposition chamber 60 must change accordingly. Narrowing pole piece 226 by 14 mm may offset this change and permit use of substantially the same apparatus described for the preferred embodiment.

### EXAMPLE

The configurations depicted in FIGS. 9 and 12 were constructed for a 4300 PVD system and the magnetic flux density measured across target 10 using a 3-axis Hall-effect probe. Magnetic flux proved more widely distributed for the 45° oriented perimeter magnets 124 of the system of FIG. 12 than for the 90° degree oriented perimeter magnets 24 of the system of FIG. 9. Specifically, flux density increased from 100 to 600 gauss in free electron region 129 between inner and outer magnets 22, 124 and attenuated by 50 to 200 gauss in other regions of target 10 where development of grooves 25, 27 was greatest for the 90° system. Further, DC output voltage for the 45° system was 35% lower than for the 90° system for a constant power output level.

While the invention has been particularly shown and described with reference to a preferred embodiment, it will be understood by those skilled in the art that various changes in form and detail may be made therein without departing from the spirit and scope of the invention. For example, the second preferred embodiment has been discussed above in conjunction with the tilted target 10 of the preferred and first alternate embodiments. The benefits of spreading the flux from inner and outer magnets 22, 24 may be achieved independently of this target orientation, however, and produce similar benefits for targets 10 oriented at all angles from vertical to horizontal.

We claim:

1. An apparatus for sputter deposition of material from a sputtering target onto a substrate, comprising:
a first sputtering target having a perimeter, a front surface and a rear surface opposite the front surface;
a first set of one or more inner magnetic poles, each having the same polarity, mounted adjacent the rear surface;
a first set of one or more outer magnetic poles, each having a polarity opposite the polarity of the inner magnetic poles, mounted adjacent the rear surface juxtaposed to the perimeter of the first target, wherein
the first set of outer magnetic poles collectively encircles the first set of inner magnetic poles; and
each one of the outer magnetic poles is magnetized at an acute magnetization angle relative to the front surface.

2. Apparatus according to claim 1 wherein:
each one of the inner magnetic poles is magnetized in a direction perpendicular to the front surface.

3. Apparatus according to claim 1 wherein:
the magnetization angle of the outer magnetic poles is between thirty and sixty degrees, inclusive, relative to the front surface.

4. Apparatus according to claim 3 wherein:
the magnetization angle of the outer magnetic poles is directed radially outward and away from the inner magnetic poles.

5. Apparatus according to claim 1 wherein:
the magnetization angle of the outer magnetic poles is between thirty and sixty degrees, inclusive, relative to the front surface; and
each one of the inner magnetic poles is magnetized in a direction perpendicular to the front surface.

6. Apparatus according to claim 1 wherein:
the magnetization angle of each of the outer magnetic poles causes magnetic flux from that magnetic pole to be directed radially outward and away from the inner magnetic poles.

7. Apparatus according to claim 6 wherein:
the magnetization angle of each of the outer magnetic poles causes magnetic flux from that magnetic pole be directed beyond the perimeter of the first target.

8. Apparatus according to claim 1 wherein:
the magnetization angle of each of the outer magnetic poles causes magnetic flux from the first set of outer magnetic poles to be oriented substantially parallel to the front surface of the first target.

9. Apparatus according to claim 1 wherein:
the magnetization angle of the outer magnetic poles is between thirty and sixty degrees, inclusive, relative to the front surface, and directed radially outward and away from the inner magnetic poles;
magnetic flux from the outer magnetic poles is substantially parallel to the front surface of the first target; and
each one of the inner magnetic poles is magnetized in a direction perpendicular to the front surface.

10. Apparatus according to claim 1 wherein:
the rear surface is directed generally upward; and
the front surface is directed generally downward toward the substrate.

11. Apparatus according to claim 10 wherein:
the magnetization angle of the outer magnetic poles is between thirty and sixty degrees, inclusive, relative to the front surface; and
each one of the inner magnetic poles is magnetized in a direction perpendicular to the front surface.

12. Apparatus according to claim 10 wherein:
the magnetization angle of each of the outer magnetic poles causes magnetic flux from that magnetic pole to be directed radially outward and away from the inner magnetic poles.

13. Apparatus according to claim 12 wherein:
the magnetization angle of each of the outer magnetic poles causes magnetic flux from that magnetic pole be directed beyond the perimeter of the first target.

14. Apparatus according to claim 10 and further comprising:
a vacuum chamber enclosing the first target; and
a workpiece support for positioning a substrate at one or more workpiece positions within the vacuum chamber, wherein said one or more workpiece positions include one or more workpiece positions that are below the first target.

15. Apparatus according to claim 10 wherein:
the front surface is tilted at an angle in the range of 30 to 60 degrees, inclusive, relative to a vertical line.

16. Apparatus according to claim 15 wherein:
the magnetization angle of the outer magnetic poles is between thirty and sixty degrees, inclusive, relative to the front surface; and
each one of the inner magnetic poles is magnetized in a direction perpendicular to the front surface.

17. Apparatus according to claim 15 wherein:
the magnetization angle of each of the outer magnetic poles causes magnetic flux from that magnetic pole to be directed radially outward and away from the inner magnetic poles.

18. Apparatus according to claim 17 wherein:
the magnetization angle of each of the outer magnetic poles causes magnetic flux from that magnetic pole be directed beyond the perimeter of the first target.

19. Apparatus according to claim 10 wherein:
the first sets of inner and outer magnetic poles are mounted so that the collective average distance between them and the front surface of the first target is less than half the width of the front surface of the first target.

20. Apparatus according to claim 19 wherein:
the front surface is tilted at an angle in the range of 30 to 60 degrees, inclusive, relative to a vertical line.

21. Apparatus according to claim 19 wherein:
the magnetization angle of the outer magnetic poles is between thirty and sixty degrees, inclusive, relative to the front surface.

22. Apparatus according to claim 19 wherein:
the magnetization angle of the outer magnetic poles is directed radially outward and away from the inner magnetic poles.

23. Apparatus according to claim 19 wherein:
the magnetization angle of each of the outer magnetic poles causes magnetic flux from the first set of outer magnetic poles to be oriented substantially parallel to the front surface of the first target.

24. Apparatus according to claim 1 and further comprising
a second sputtering target having a second perimeter, a second front surface and a second rear surface opposite the second front surface;
a second set of one or more inner magnetic poles, each having the same polarity, mounted adjacent the second rear surface;
a second set of one or more outer magnetic poles, each having a polarity opposite the polarity of the inner magnetic poles, mounted adjacent the second rear surface juxtaposed to the second perimeter, wherein
the second set of outer magnetic poles collectively encircles the second set of inner magnetic poles; and
each one of the outer magnetic poles of the second set of outer magnetic poles is magnetized at an acute magnetization angle relative to the second front surface.

25. Apparatus according to claim 24 wherein:
the magnetization angles of the first and second sets of outer magnetic poles are between thirty and sixty degrees, inclusive, relative to the front surfaces of the first and second targets, respectively, and directed radially outward and away from the respective sets of inner magnetic poles;
magnetic flux from the first and second sets of outer magnetic poles is substantially parallel to the front surface of the first and second targets respectively; and
each one of the inner magnetic poles of the first and second sets of inner magnetic poles is magnetized in a direction perpendicular to the front surface of the first and second targets respectively.

26. Apparatus according to claim 24 wherein:
the rear surface of each target is directed generally upward; and
the front surface of each target is directed generally downward toward the substrate.

27. Apparatus according to claim 26 wherein:
the first and second targets are oriented symmetrically relative to, and on opposite sides of, a vertical plane of symmetry, so that the front surface of each target is oriented toward the front surface of the other target.

28. Apparatus according to claim 26 wherein:
each of the first and second targets is oriented at an orientation angle relative to the vertical plane that is equal and opposite the orientation angle of the other target.

29. Apparatus according to claim 29 wherein:
the orientation angles of the first and second targets are in the range of 30 to 60 degrees, inclusive, relative to said vertical plane.

30. Apparatus according to claim 26 and further comprising:
a vacuum chamber enclosing the first and second targets; and
a workpiece support for positioning an electronic substrate at one or more workpiece positions within the vacuum chamber, wherein said one or more workpiece positions include one or more workpiece positions that are below the first target and one or more workpiece positions that are below the second target.

31. Apparatus according to claim 30 wherein:
the first and second targets are oriented symmetrically relative to, and on opposite sides of, a vertical plane of symmetry, so that the front surface of each target is oriented toward the front surface of the other target.

32. Apparatus according to claim 26 wherein:
the magnetization angles of the first and second sets of outer magnetic poles is between thirty and sixty degrees, inclusive, relative to the front surfaces of the first and second targets respectively; and
each one of the inner magnetic poles of the first and second sets of inner magnetic poles is magnetized in a direction perpendicular to the front surface of the first and second targets respectively.

33. Apparatus according to claim 26 wherein:
the magnetization angles of each of the outer magnetic poles of the first and second sets of magnetic poles causes magnetic flux from the first and second sets of magnetic poles respectively to be directed radially outward and away from the inner magnetic poles of the first and second sets of inner magnetic poles.

34. Apparatus according to claim 33 wherein:
the magnetic flux from the first and second sets of outer magnetic poles is directed beyond the perimeter of the first and second targets respectively.

35. A method of sputter depositing material from a sputtering target onto a substrate, comprising the steps of:
mounting within a vacuum chamber a first sputtering target having a perimeter, a front surface and a first rear surface opposite the front surface;
mounting a first set of one or more inner magnetic poles, each having the same polarity, adjacent the rear surface;
mounting a first set of one or more outer magnetic poles, each having a polarity opposite the polarity of the inner magnetic poles, adjacent the rear surface adjacent to the perimeter of the first target, wherein
the first set of outer magnetic poles collectively encircles the first set of inner magnetic poles; and
each one of the outer magnetic poles is magnetized at an acute magnetization angle relative to the front surface; and
sputtering material from the first target onto the substrate.

36. A method according to claim 35 and further comprising the step of:
positioning the substrate at one or more workpiece positions within the vacuum chamber, wherein said one or more workpiece positions include one or more workpiece positions that are below the first target.

37. A method according to claim 35, further comprising the steps of:
mounting a second sputtering target within the vacuum chamber, the second target having second perimeter, second front surface and a second rear surface opposite the second front surface;
mounting a second set of one or more inner magnetic poles, each having the same polarity, adjacent the second rear surface;
mounting a second set of one or more outer magnetic poles, each having a polarity opposite the polarity of the inner magnetic poles, adjacent the second rear surface and the perimeter of the second target, wherein
the second set of outer magnetic poles collectively encircles the second set of inner magnetic poles; and
each one of the outer magnetic poles of the second set is magnetized at an acute magnetization angle relative to the front surface of the second target; and
sputtering material from the second target onto the substrate.

38. A method according to claim 35 and further comprising the step of:
positioning the substrate at one or more workpiece positions within the vacuum chamber, wherein said one or more workpiece positions include one or more workpiece positions that are below the first and second targets.

39. A method according to claim 38 wherein the steps of mounting the first and second targets further comprise the steps of
positioning the first and second targets equidistant from and symmetric about a vertical plane of symmetry wherein the front faces of the first and second targets face generally downward and toward each other and toward the one or more workpiece positions that are below the targets.

40. A method according to claim 35 wherein:
the magnetization angles of the first and second sets of outer magnetic poles is between thirty and sixty degrees, inclusive, relative to the front surfaces of the first and second targets respectively; and
each one of the inner magnetic poles of the first and second sets of inner magnetic poles is magnetized in a direction perpendicular to the front surface of the first and second targets respectively.

41. A method according to claim 35 wherein:
the magnetization angles of each of the outer magnetic poles of the first and second sets of magnetic poles causes magnetic flux from the first and second sets of magnetic poles respectively to be directed radially outward and away from the inner magnetic poles of the first and second sets of inner magnetic poles.

42. A method according to claim 41 wherein:
the magnetic flux from the first and second sets of outer magnetic poles is directed beyond the perimeter of the first and second targets respectively.

43. An apparatus for sputter deposition of material from a sputtering target onto a substrate, comprising:
a first sputtering target having a first perimeter, a front surface facing generally downward and a rear surface opposite the front surface and facing generally upward;
a first set of one or more inner magnetic poles, each having the same polarity, mounted adjacent the rear surface;
a first set of one or more outer magnetic poles, each having a polarity opposite the polarity of the inner magnetic poles, mounted adjacent the rear surface and the first perimeter, wherein
the first set of outer magnetic poles collectively encircles the first set of inner magnetic poles; and
each one of the outer magnetic poles is physically oriented at an orientation angle between thirty and sixty degrees relative to the first front surface, the orientation angle being directed radially outward and away from the first set of inner magnetic poles.

44. Apparatus according to claim 43 and further comprising
a second sputtering target having a second perimeter, a second front surface and a second rear surface opposite the second front surface;
a second set of one or more inner magnetic poles, each having the same polarity, mounted adjacent the second rear surface;
a second set of one or more outer magnetic poles, each having a polarity opposite the polarity of the inner magnetic poles, mounted adjacent the second rear surface juxtaposed to the second perimeter, wherein
the second set of outer magnetic poles collectively encircles the second set of inner magnetic poles; and
each one of the outer magnetic poles of the second set of outer magnetic poles is oriented at an orientation angle between thirty a nd sixty degrees relative to the second front surface, the orientation angle being directed radially outward and away from the second set of inner magnetic poles.

45. A method of sputter depositing material from a sputtering target onto a substrate, comprising the steps of
mounting within a vacuum chamber a first sputtering target having a first perimeter, a front surface facing generally downward and a rear surface opposite the front surface and facing generally upward;
mounting a first set of one or more inner magnetic poles, each having the same polarity, adjacent the rear surface;
mounting a first set of one or more outer magnetic poles, each having a polarity opposite the polarity of the inner magnetic poles, adjacent the rear surface and the first perimeter, wherein
the first set of outer magnetic poles collectively encircles the first set of inner magnetic poles; and
each one of the outer magnetic poles is physically oriented at an orientation angle between thirty and sixty degrees relative to the first front surface, the orientation angle being directed radially outward and away from the first set of inner magnetic poles; and
sputtering material from the first target onto the substrate.

46. A method according to claim 45 and further comprising the steps of:
mounting a second sputtering target within the vacuum chamber, the second target having second perimeter, second front surface and a second rear surface opposite the second front surface;
mounting a second set of one or more inner magnetic poles, each having the same polarity, adjacent the second rear surface;
mounting a second set of one or more outer magnetic poles, each having a polarity opposite the polarity of the inner magnetic poles, adjacent the second rear surface and the perimeter of the second target, wherein
the second set of outer magnetic poles collectively encircles the second set of inner magnetic poles; and
each one of the outer magnetic poles of the second set is physically oriented at an orientation angle between thirty and sixty degrees relative to the second front surface, the orientation angle being directed radially outward and away from the second set of inner magnetic poles; and
sputtering material from the second target onto the substrate.
